(19) United States
(12) Patent Application Publication
(10) Pub. No.: US 2025/0176330 A1
(43) Pub. Date: May 29, 2025

(54) LIGHT EMITTING ASSEMBLY AND LIGHT EMITTING DEVICE

(71) Applicant: Wistron NeWeb Corporation, Hsinchu (TW)

(72) Inventors: Yu-Shuo WU, Hsinchu (TW); Chia Yu LI, Hsinchu (TW)

(21) Appl. No.: 18/954,726

(22) Filed: Nov. 21, 2024

(30) Foreign Application Priority Data
Nov. 24, 2023 (TW) 112145526

(51) Int. Cl. H01L 33/58; H01L 25/075

(52) U.S. Cl. CPC H10H 20/855; H01L 25/0753

(57) ABSTRACT

A light emitting assembly includes a substrate, a plurality of light emitting elements and at least one blocking element. The light emitting elements are disposed on the substrate. The blocking element is located between two adjacent of the light emitting elements, wherein the blocking element is made of a light curing material.

### RELATED APPLICATIONS

This application claims the benefit of priority to Taiwan Patent Application Serial No. 112145526, filed on Nov. 24, 2023. The entire content of the above identified application is incorporated herein by reference.

### BACKGROUND

### Technical Field

The present disclosure relates to a light emitting assembly and a light emitting device. More particularly, the present disclosure relates to a light emitting assembly and a light emitting device capable of blocking light.

### Description of Related Art

With the development of 3C products, related industries have developed many light emitting devices, and light emitting elements such as LED light emitting elements are directly placed on substrates and used as light sources for electronic product screens or some indicator lights. However, when light emitting elements of different colors are placed on the same substrate, the light from different light emitting elements will interfere with each other, affecting the display of color or brightness. To solve this problem, related industries have used foam or soft materials to make blocking elements which are attached to the substrate to separate the light emitting elements and block the light to avoid the light interference. However, the foam materials are soft and may fall off due to insufficient adhesive force during attachment, or require a large area for stable attachment. Additionally, the foam materials need to be manually attached, which can easily lead to misalignment, difficulty in assembly and residual adhesive during rework, affecting the assembling efficiency and application stability of the light emitting device.

In view of this, a light emitting assembly and a light emitting device that can improve assembling efficiency and using stability is a common goal for related industries.

### SUMMARY

According to one aspect of the present disclosure, a light emitting assembly includes a substrate, a plurality of light emitting elements and at least one blocking element. The plurality of light emitting elements are disposed on the substrate. The at least one blocking element is located between two adjacent of the plurality of light emitting elements, wherein the at least one blocking element is made of a light curing material.

According to another aspect of the present disclosure, a light emitting assembly includes a substrate, a plurality of light emitting elements and at least one blocking element. The plurality of light emitting elements are disposed on the substrate, wherein each of the plurality of light emitting elements emits light to an incident surface. The at least one blocking element is located between two adjacent of the plurality of light emitting elements. A blocking wall height of the at least one blocking element is h1, an incident height between the incident surface corresponding to each of the plurality of light emitting elements and the substrate is h2, a height of each of the plurality of light emitting elements is h3, an incident distance between a projected position of the incident surface adjacent to the at least one blocking element on the substrate and a center point of the corresponding light emitting element is a, a first distance between the incident surface and the at least one blocking element is b, and a second distance between another incident surface and the at least one blocking element is c, which satisfy the following condition: h1≥ {[(h2-h3) (a+b)]/(a+b+c)}+h3.

According to further another aspect of the present disclosure, a light emitting device includes a substrate, a structural element, a plurality of light emitting elements, a plurality of light guiding elements and at least one blocking element. The structural element is located above the substrate and has a spacing distance from the substrate. The plurality of light emitting elements are disposed between the substrate and the structural element. Each of the plurality of light guiding elements is disposed between each of the plurality of light emitting elements and the structural element, and each of the plurality of light guiding elements has an incident surface. The at least one blocking element is disposed on at least one of the substrate and the structural element, and the at least one blocking element is located between two adjacent of the plurality of light emitting elements.

### BRIEF DESCRIPTION OF THE DRAWINGS

The present disclosure can be more fully understood by reading the following detailed description of the embodiment, with reference made to the accompanying drawings as follows:

FIG. 1 is a side view of a light emitting assembly according to a first embodiment of the present disclosure.

FIG. 2 is a top view of the light emitting assembly according to the first embodiment of FIG. 1.

FIG. 3 is a schematic view of a light emitting assembly according to a second embodiment of the present disclosure.

FIG. 4 is a cross-sectional view of a light emitting device according to a third embodiment of the present disclosure.

FIG. 5 is a cross-sectional view of a light emitting device according to a fourth embodiment of the present disclosure.

### DETAILED DESCRIPTION

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

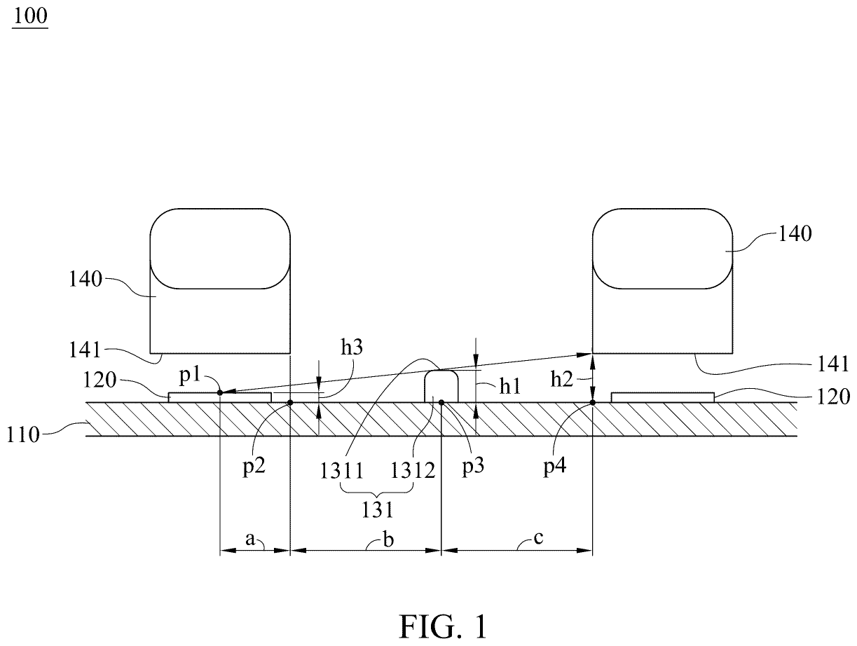

Referring to FIG. 1, which is a side view of a light emitting assembly 100 according to a first embodiment of the present disclosure. As shown in FIG. 1, the light emitting assembly 100 includes a substrate 110, a plurality of light emitting elements 120 and at least one blocking element 131 (FIG. 1 only shows two light emitting elements 120 and one blocking element 131, but the present disclosure is not limited to these quantities). The light emitting elements 120 are disposed on the substrate 110. The blocking element 131 is located between two adjacent of the light emitting elements 120, and the blocking element 131 is made of a light curing material. Further, the light curing material can be a photocurable colloidal material.

The blocking element 131 made from the photocurable colloidal material is solidified by exposure to light and fixed between adjacent light emitting elements 120 to prevent interference between the light emitted by the light emitting elements 120. This design avoids the issue associated with conventional foam material blocking elements, where excessive adhesive area reduces the space available for other components on the substrate 110. As a result, the assembling efficiency of the light emitting assembly 100 can be enhanced, and the using stability thereof can be improved. The structural details of the light emitting assembly 100 will be described below.

During the assembling process of the light emitting assembly 100, the light emitting elements 120 can be disposed on the substrate 110, and then the blocking element 131 made of the light curing material is disposed between the adjacent light emitting elements 120. Next, the blocking element 131 is irradiated with light to solidify and be fixed on the substrate 110. It should be mentioned that the present disclosure is not limited to the aforementioned manufacturing method.

The light curing material can include an acrylic resin base, and the light curing material can be used to block the light emitted by the light emitting elements 120. The light curing material with the acrylic resin base has the characteristics of compressibility, fast curing and no residual adhesive when peeled off. Furthermore, the light curing material is an ultraviolet grease made of the acrylic resin base. In other words, the light curing material can be cured by light irradiation, and the light curing material with low transmittance can block light. In this way, during the assembling process of the light emitting assembly 100, an automated arm can hold an injection device filled with the light curing material, and then the light curing material can be dispensed between the adjacent light emitting elements 120. After that, the light curing material is exposed to light for rapid solidification and curing and forms the blocking element 131 which is dark or opaque. Therefore, the blocking element 131 can be stably and quickly disposed between the light emitting elements 120, avoiding the risk of the blocking element made of conventional foam materials falling off due to insufficient adhesive force, thereby improving using stability. Furthermore, the light curing material with low transmittance can provide sufficient light blocking efficiency to avoid light interference between the adjacent light emitting elements 120.

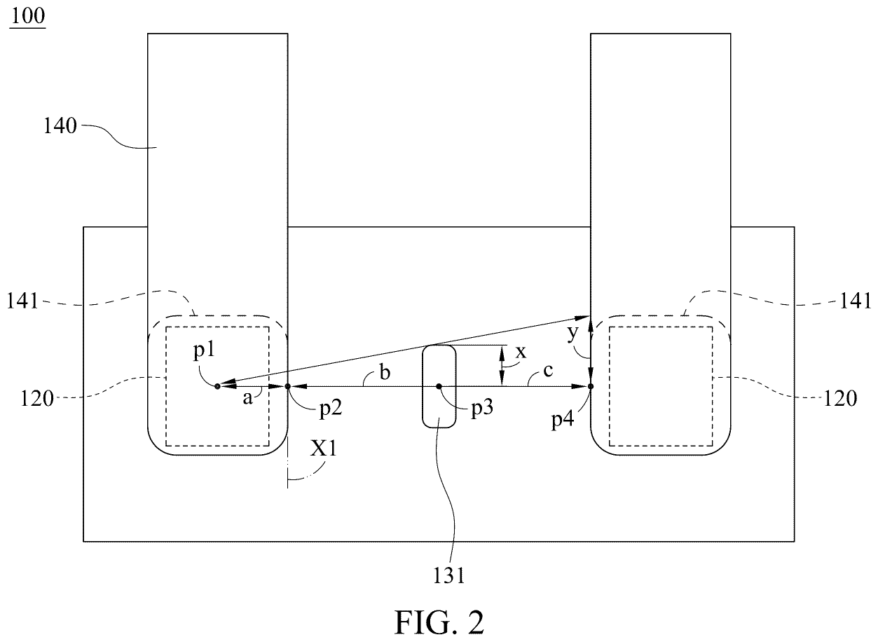

Referring to FIG. 2, which is a top view of the light emitting assembly 100 according to the first embodiment of FIG. 1. As shown in FIG. 1 and FIG. 2, the blocking element 131 can include a supporting portion 1312 and a top portion 1311. The supporting portion 1312 extends in a direction perpendicular to the substrate 110, and the top portion 1311 is integrally disposed on the supporting portion 1312. The shape of the top portion 1311 is a semi-cylindrical shape. From a side view perspective, the shape of the entire blocking element 131 can be approximately bell-shaped. In other embodiments, the shape of the supporting portion can be pyramid-shaped or other shapes, and the present disclosure does not limit the shape of the blocking element. From a top view perspective, the shape of the blocking element 131 can be a strip shape. This can reduce the material usage of the blocking element 131 to lower manufacturing costs.

As shown in FIG. 1, each light emitting element 120 emits light to an incident surface 141. Each incident surface 141 can be a surface of the light guiding element 140 closest to the light emitting element 120 on the light emitting assembly 100, so that the light emitted by the light emitting element 120 can be guided into the corresponding light guiding element 140. However, the present disclosure is not limited thereto. When a blocking wall height of the blocking element 131 is h1, an incident height between the incident surface 141 corresponding to each light emitting element 120 and the substrate 110 is h2, a height of each light emitting element 120 is h3, an incident distance between a projected position of the incident surface 141 adjacent to the blocking element 131 on the substrate 110 and a center point p1 of the corresponding light emitting element 120 is a, a first distance between the incident surface 141 and the blocking element 131 is b, and a second distance between another incident surface 141 and the blocking element 131 is c. As shown in FIG. 1 and FIG. 2, the position where each incident surface 141 projects onto the substrate 110 can define reference projection points p2, p4. Because the incident surface 141 is rectangular, the side of the incident surface 141 closest to the blocking element 131 forms a projection line X1 when projected onto the substrate 110. The center of the projection line X1 is the reference projection point p2, and the incident distance between the center point p1 and the reference projection point p2 is a. The first distance b between the incident surface 141 and the blocking element 131 is the distance between the reference projection point p2 and the center p3 of the blocking element 131. The second distance c between the another incident surface 141 and the blocking element 131 is the distance between the reference projection point p4 and the center p3 of the blocking element 131. Further, the following condition is satisfied: h1≥{[(h2−h3) (a+b)]/(a+b+c)}+h3. Furthermore, when h1>{[(h2−h3) (a+b)]/(a+b+c)}+h3 is satisfied, the light blocking effect can be further enhanced. Thus, when the light emitting element 120 emits light, the blocking wall height h1 of the blocking element 131 can block the light emitted by the adjacent light emitting element 120 that does not enter the corresponding incident surface 141. The light that is not blocked by the blocking element 131 can only enter the outer edge of the adjacent light guiding element 140, thereby avoiding the possibility of light from the light emitting element 120 entering other adjacent incident surfaces 141, preventing the light interference between the light emitting elements 120 and reducing the material cost of the blocking element 131. As shown in FIG. 2, when half of a length of each incident surface 141 is y, and half of a length of the blocking element 131 is x, which satisfy the following condition: x≥y(a+b)/(a+b+c). Furthermore, when x>y(a+b)/(a+b+c) is satisfied, the light blocking effect can be further enhanced.

From a top view perspective, the light emitted by the light emitting element 120 radiates from the center point p1. The light within the incident range formed by connecting the center point p1 and an endpoint of the blocking element 131 will be blocked by the blocking element 131 and cannot enter the adjacent light emitting element 120, further avoiding interference of light between the light emitting elements 120.

As shown in FIG. 2, the area of the incident surface 141 is larger than the area of the light emitting element 120. In other words, the area of the incident surface 141 is larger than the area of the light emitting surface of the light emitting element 120, so that most of the light emitted by the light emitting element 120 can directly enter the incident surface 141. In other embodiments, the area of the incident surface can be smaller than the area of the light emitting surface of the light emitting element. The area of the incident surface in the present disclosure can be changed according to actual needs and is not limited thereto.

In the first embodiment, there is a gap between the blocking element 131 and each of the light emitting elements 120 to avoid interference between the light emitting elements 120. In other embodiments, the blocking element can abut against the light emitting element, and the area of the incident surface is smaller than the area of the light emitting surface of the light emitting element. Therefore, the blocking element can block the light and prevent interference from the light emitted from the light emitting surface of the light emitting element entering the incident surface. The blocking element in the present disclosure can be arranged according to needs and is not limited thereto.

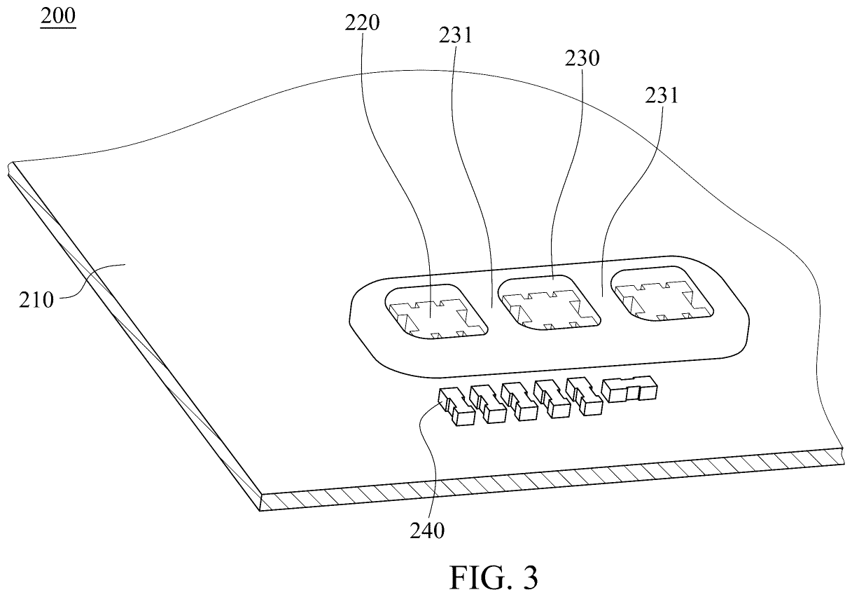

Referring to FIG. 3, which is a schematic view of a light emitting assembly 200 according to a second embodiment of the present disclosure. In the second embodiment, the light emitting assembly 200 includes a substrate 210, a plurality of light emitting elements 220, a plurality of blocking elements 231 and a plurality of electronic elements 240, and the structures and configurations of the substrate 210, the light emitting elements 220 and the blocking elements 231 are similar to the structures and configurations of the substrate 110, the light emitting elements 120 and the blocking elements 131 in the first embodiment, so that the details thereof will not be described herein. The electronic elements 240 are disposed on the substrate 210, and the electronic elements 240 can be control modules for controlling the light emission of the light emitting elements 220 or modules for performing other functions of the light emitting assembly 200, and the present disclosure is not limited thereto. Particularly, the light emitting assembly 200 can further include a blocking structure 230. The blocking structure 230 is integrally formed on the substrate 210 and surrounds the light emitting elements 220, wherein the blocking element 231 is part of the blocking structure 230. Furthermore, the blocking element 231 can be made of a gel material, which is different from the blocking element 131 made of a light curing material in the first embodiment. In other words, the blocking element in the present disclosure is not necessarily made of a light curing material and is not limited to the above materials. When the blocking wall height of the blocking elements 231 satisfies the conditions in the first embodiment, the blocking structure 230 can surround the light emitting elements 220 to form separate light emitting spaces, avoiding the light from the light emitting elements 220 entering adjacent light emitting spaces and reducing the possibility of light interference.

In other embodiments, the light emitting assembly can further include at least one board element, and part of the board element is embedded in the blocking element. The number of the board element can be plural and correspond to the number of the blocking elements. Furthermore, through the compressibility of the blocking element made of the gel material, the board element can be inserted into the blocking element to further block the light emitted from the light emitting element towards other adjacent incident surfaces. Furthermore, the board element can be disposed on a counterpart corresponding to the substrate, so that the distance between the substrate and the counterpart can be further fixed through the board element embedded in the blocking element, but the present disclosure is not limited thereto.

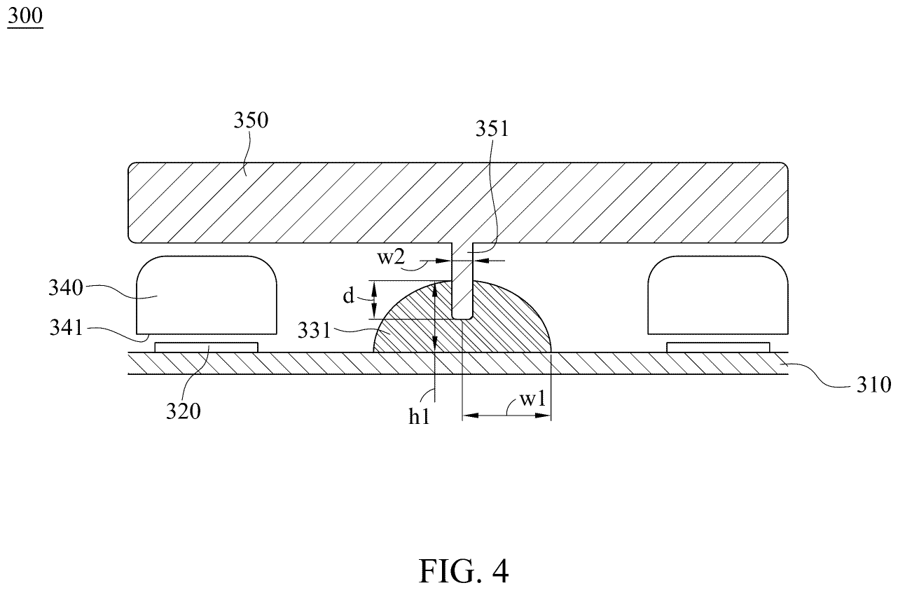

Referring to FIG. 4, which is a cross-sectional view of a light emitting device 300 according to a third embodiment of the present disclosure. The light emitting device 300 includes a substrate 310, a structural element 350, a plurality of light emitting elements 320, a plurality of light guiding elements 340 and a blocking element 331. The structural element 350 is located above the substrate 310 and has a spacing distance from the substrate 310. The light emitting elements 320 are disposed between the substrate 310 and the structural element 350. Each light guiding element 340 is disposed between each light emitting element 320 and the structural element 350, and each light guiding element 340 has an incident surface 341. The blocking element 331 is disposed on at least one of the substrate 310 and the structural element 350, wherein the blocking element 331 is located between two adjacent of the light emitting elements 320. It must be noted that a blocking wall height h1 of the blocking element 331 in the third embodiment can satisfy the conditions of the blocking wall height h1 of the blocking element 131 in the first embodiment, and the conditions thereof will not be described herein.

In the third embodiment, the blocking element 331 is disposed on the substrate 310, and the blocking element 331 is made of a light curing material. The structural element 350 can include at least one board element 351. The board element 351 extends from the structural element 350 towards the substrate 310, and part of the board element 351 is embedded in the blocking element 331. The board element 351 can be an opaque plastic part or a metal part, but the present disclosure is not limited thereto. Further, the blocking wall height h1 of the blocking element 331, half of a width w1 of the blocking element 331, a width w2 of the board element 351 and a depth d of the part of the board element 351 embedded in the blocking element 331 can satisfy the following condition: w2×d≤h1×w1(2−0.5π). When the board element 351 is embedded in the blocking element 331, the blocking element 331 deforms towards its sides due to its compressibility, and the above condition can avoid the blocking element 331 from covering the adjacent light emitting element 320 due to compression, thereby preventing the light emitted by the light emitting element 320 to the corresponding incident surface 341 from being blocked or even preventing damaging the light emitting element 320. Furthermore, when w2×d<h1×w1(2−0.5π) is satisfied, the possibility of the blocking element 331 affecting the light emitting element 320 can be further reduced. Therefore, through the configuration of the board element 351 and the blocking element 331, the light emitting elements 320 can be separated from each other, which can prevent light interference between different light emitting elements 320 while maintaining the normal light emission of the light emitting elements 320. As shown in FIG. 4, the shape of the blocking element 331 is hemispherical, and the blocking wall height h1 is equal to half the width w1 of the blocking element 331 and equal to the radius of the blocking element 331. In other embodiments, the blocking wall height of the blocking element may not be equal to half the width of the blocking element. The present disclosure is not limited to the shape of the blocking element described above.

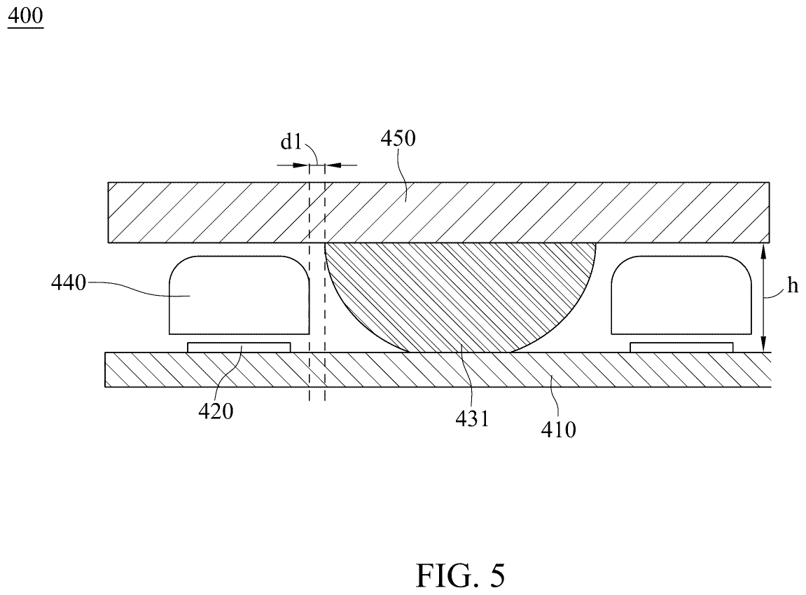

Referring to FIG. 5, which is a cross-sectional view of a light emitting device 400 according to a fourth embodiment of the present disclosure. As can be seen from FIG. 5, the structures of the substrate 410, the structural element 450, the light emitting elements 420, the light guiding elements 440 and the blocking element 431 of the light emitting device 400 in the fourth embodiment are similar to that of the substrate 310, the structural element 350, the light emitting elements 320, the light guiding elements 340 and the blocking element 331 of the light emitting device 300 in the third embodiment, so that the details thereof will not be described herein.

Particularly, the blocking element 431 is disposed on the structural element 450 (or any counterpart of the substrate 410, such as a cover), and a top end of the blocking element 431 contacts the substrate 410. Furthermore, the blocking element 431 is made of a light curing material and can be compressibly in contact with the substrate 410. In other words, the blocking element 431 has a blocking wall height greater than a spacing distance h between the structural element 450 and the substrate 410 before contacting the substrate 410, and the blocking element 431 compresses after contacting the substrate 410, thereby completely separating the spaces of the two adjacent of the light emitting elements 420 to ensure light blocking and avoid light interference.

Furthermore, there can be a spacing d1 between the blocking element 431 and each light guiding element 440. When the top end of the blocking element 431 contacts the substrate 410, the blocking element 431 compresses and deforms towards its sides, and the spacing d1 between the blocking element 431 and each light guiding element 440 can avoid the blocking element 431 from touching the light guiding element 440 due to deformation, thereby avoiding the possibility of the light guiding element 440 being displaced or damaged.

The light emitting device 400 can further include a blocking structure (not shown). The blocking structure is integrally formed on the structural element 450 and surrounds the light emitting elements 420, wherein the blocking element 431 is part of the blocking structure. In the fourth embodiment, the blocking structure can surround the light emitting elements 420 as in the blocking structure 230 of the second embodiment. The difference is that the blocking structure 230 of the second embodiment is formed on the substrate 210, while in the fourth embodiment, the blocking structure containing the blocking element 431 is formed on the structural element 450. Thus, when the structural element 450 is not yet covered on the substrate 410, the blocking structure can be formed on the structural element 450 by dispensing, to create a grid-like space to accommodate the light emitting elements 420. Furthermore, after the light emitting elements 420 and the light guiding elements 440 are assembled on the substrate 410, the structural element 450 is installed on the substrate 410, and the blocking structure is disposed to surround the light emitting elements 420 and the light guiding elements 440 to avoid light interference.

From the above embodiments, it can be seen that the light emitting assembly and the light emitting device provided by the present disclosure have the following advantages. First, the blocking element made of a light curing material can improve the assembling efficiency of the light emitting assembly. Second, the blocking wall height and the length of the blocking element can satisfy the specific conditions to ensure light blocking while reducing material costs. Third, the configuration of the board element can effectively prevent light interference between light emitting elements.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A light emitting assembly, comprising:
a substrate;
a plurality of light emitting elements disposed on the substrate; and
at least one blocking element located between two adjacent of the plurality of light emitting elements, wherein the at least one blocking element is made of a light curing material.

2. The light emitting assembly as claimed in claim 1, wherein the light curing material comprises an acrylic resin base.

3. The light emitting assembly as claimed in claim 1, wherein the light curing material is used to block light emitted by each of the plurality of light emitting elements.

4. The light emitting assembly as claimed in claim 1, wherein a blocking wall height of the at least one blocking element is h1, each of the plurality of light emitting elements is used to emit light to an incident surface, an incident height between the incident surface corresponding to each of the plurality of light emitting elements and the substrate is h2, a height of each of the plurality of light emitting elements is h3, an incident distance between a projected position of the incident surface adjacent to the at least one blocking element on the substrate and a center point of the corresponding light emitting element is a, a first distance between the incident surface and the at least one blocking element is b, and a second distance between another incident surface and the at least one blocking element is c, which satisfy the following condition:
$$h 1 \geq \{ [ ( h 2 - h 3 ) ( a + b ) ] / ( a + b + c ) \} + h 3 .$$

5. The light emitting assembly as claimed in claim 4, wherein half of a length of each incident surface is y, and half of a length of the at least one blocking element is x, which satisfy the following condition:
$$x \geq y ( a + b ) / ( a + b + c ) .$$

6. The light emitting assembly as claimed in claim 1, further comprising:
a blocking structure integrally formed on the substrate and surrounding the plurality of light emitting elements, wherein the at least one blocking element is part of the blocking structure.

7. The light emitting assembly as claimed in claim 1, further comprising:
at least one board element, wherein part of the at least one board element is embedded in the at least one blocking element.

8. The light emitting assembly as claimed in claim 7, wherein a blocking wall height of the at least one blocking element is h1, half of a width of the at least one blocking element is w1, a width of the at least one board element is w2, and a depth of the part of the at least one board element embedded in the at least one blocking element is d, which satisfy the following condition:
$$w 2 \times d \leq h 1 \times w 1 ( 2 - 0.5 π ) .$$

9. A light emitting assembly, comprising:
a substrate;
a plurality of light emitting elements disposed on the substrate, wherein each of the plurality of light emitting elements emits light to an incident surface; and
at least one blocking element located between two adjacent of the plurality of light emitting elements;
wherein a blocking wall height of the at least one blocking element is h1, an incident height between the incident surface corresponding to each of the plurality of light emitting elements and the substrate is h2, a height of each of the plurality of light emitting elements is h3, an incident distance between a projected position of the incident surface adjacent to the at least one blocking element on the substrate and a center point of the corresponding light emitting element is a, a first distance between the incident surface and the at least one blocking element is b, and a second distance between another incident surface and the at least one blocking element is c, which satisfy the following condition:
$$h 1 \geq \{ [ ( h 2 - h 3 ) ( a + b ) ] / ( a + b + c ) \} + h 3 .$$

10. The light emitting assembly as claimed in claim 9, wherein the at least one blocking element comprises a supporting portion and a top portion, the supporting portion extends in a direction perpendicular to the substrate, and the top portion is integrally disposed on the supporting portion and has a semi-cylindrical shape.

11. The light emitting assembly as claimed in claim 9, wherein the at least one blocking element is made of a gel material.

12. A light emitting device, comprising:
a substrate;
a structural element located above the substrate and having a spacing distance from the substrate;
a plurality of light emitting elements disposed between the substrate and the structural element;
a plurality of light guiding elements, each of the plurality of light guiding elements disposed between each of the plurality of light emitting elements and the structural element, and each of the plurality of light guiding elements having an incident surface; and
at least one blocking element disposed on at least one of the substrate and the structural element, wherein the at least one blocking element is located between two adjacent of the plurality of light emitting elements.

13. The light emitting device as claimed in claim 12, wherein the at least one blocking element is disposed on the structural element, and a top end of the at least one blocking element contacts the substrate.

14. The light emitting device as claimed in claim 13, further comprising:
a blocking structure integrally formed on the structural element and surrounding the plurality of light emitting elements, wherein the at least one blocking element is part of the blocking structure.

15. The light emitting device as claimed in claim 13, wherein there is a spacing between the at least one blocking element and each of the plurality of light guiding elements.

16. The light emitting device as claimed in claim 13, wherein the at least one blocking element is made of a light curing material.

17. The light emitting device as claimed in claim 16, wherein the at least one blocking element is compressibly in contact with the substrate.

18. The light emitting device as claimed in claim 12, wherein the at least one blocking element is disposed on the substrate, and the at least one blocking element is made of a light curing material.

19. The light emitting device as claimed in claim 18, wherein the structural element comprises:
at least one board element extending from the structural element towards the substrate, wherein part of the at least one board element is embedded in the at least one blocking element.

20. The light emitting device as claimed in claim 19, wherein a blocking wall height of the at least one blocking element is h1, half of a width of the at least one blocking element is w1, a width of the at least one board element is w2, and a depth of the part of the at least one board element embedded in the at least one blocking element is d, which satisfy the following condition:
$$w 2 \times d \leq h 1 \times w 1 ( 2 - 0.5 π ) .$$
